(19) United States
(12) Patent Application Publication
(10) Pub. No.: US 2026/0247531 A1
(43) Pub. Date: Aug. 20, 2026

(54) ELECTRONIC DEVICE

(71) Applicants: Innolux Corporation, Miaoli County (TW); InnoCare Optoelectronics Corporation, Tainan City (TW)

(72) Inventors: Wen-Chi Chen, Miaoli County (TW); Pei-Chih Liu, Miaoli County (TW); Cheng-Hsiao Lin, Miaoli County (TW); Sheng-Feng Huang, Miaoli County (TW); Hsin-Hung Lin, Tainan City (TW)

(73) Assignees: Innolux Corporation, Miaoli County (TW); InnoCare Optoelectronics Corporation, Tainan City (TW)

(21) Appl. No.: 19/441,725

(22) Filed: Jan. 6, 2026

(30) Foreign Application Priority Data
Feb. 19, 2025 (TW) 114106021

(51) Int. Cl. H05K 1/11

(52) U.S. Cl. CPC H05K 1/114; H05K 2201/09227; H05K 2201/09263; H05K 2201/09472; H05K 2201/09618; H05K 2201/098

(57) ABSTRACT

An electronic device including a substrate, a first conductive layer, a first insulation layer, a second conductive layer, a second insulation layer, a third conductive layer, and a third insulation layer is provided. The first conductive layer is disposed on the substrate. The first insulation layer is disposed on the first conductive layer and includes a first opening. The second conductive layer is disposed on the first insulation layer and electronically connected to the first conductive layer through the first opening. The second insulation layer is disposed on the second conductive layer and includes a second opening. The third conductive layer is disposed on the second insulation layer and electronically connected to the second conductive layer through the second opening. The second opening does not overlap the first opening.

### CROSS-REFERENCE TO RELATED APPLICATION

This application claims the priority benefit of Taiwan application serial no. 114106021, filed on Feb. 19, 2025. The entirety of the above-mentioned patent application is hereby incorporated by reference herein and made a part of this specification.

### BACKGROUND

### Technical Field

The disclosure relates to an electronic device, and particularly relates to an electronic device that can improve the bonding performance or the production amount.

### Description of Related Art

Electronic devices, including spliced electronic devices, have been extensively utilized across various industries, such as communications, display technology, automotive, or aviation. With the rapid development of the electronic devices, there is a growing trend toward lighter and thinner designs; consequently, the demands for reliability or quality in the electronic devices have become increasingly stringent.

### SUMMARY

The disclosure provides an electronic device which is capable of improving the bonding performance or increasing the production amount.

In an embodiment of the disclosure, an electronic device includes a substrate, a first conductive layer, a first insulation layer, a second conductive layer, a second insulation layer, a third conductive layer, and a third insulation layer. The first conductive layer is disposed on the substrate. The first insulation layer is disposed on the first conductive layer and includes a first opening. The second conductive layer is disposed on the first insulation layer and electronically connected to the first conductive layer through the first opening. The second insulation layer is disposed on the second conductive layer and includes a second opening. The third conductive layer is disposed on the second insulation layer and electronically connected to the second conductive layer through the second opening. The second opening does not overlap the first opening.

### BRIEF DESCRIPTION OF THE DRAWINGS

FIG. 1A is a schematic partial top view illustrating an electronic device according to a first embodiment of the disclosure.

FIG. 1B is a schematic cross-sectional view illustrating the electronic device in FIG. 1A along a section line I-I'.

FIG. 1C is a schematic cross-sectional view illustrating the electronic device in FIG. 1A along a section line II-II'.

FIG. 2 is a schematic partial cross-sectional view illustrating an electronic device according to a second embodiment of the disclosure.

FIG. 3 is a schematic partial cross-sectional view illustrating an electronic device according to a third embodiment of the disclosure.

FIG. 4 is a schematic partial cross-sectional view illustrating an electronic device according to a fourth embodiment of the disclosure.

FIG. 5 is a schematic partial top view illustrating an electronic device according to a fifth embodiment of the disclosure.

FIG. 6A is a schematic partial top view illustrating an electronic device according to a sixth embodiment of the disclosure.

FIG. 6B is a schematic cross-sectional view illustrating the electronic device in FIG. 6A along a section line III-III'.

FIG. 7A is a schematic partial top view illustrating an electronic device according to a seventh embodiment of the disclosure.

FIG. 7B is a schematic cross-sectional view illustrating the electronic device in FIG. 7A along a section line IV-IV'.

FIG. 8 is a schematic partial top view illustrating an electronic device according to an eighth embodiment of the disclosure.

FIG. 9A is a schematic partial top view illustrating an electronic device according to a ninth embodiment of the disclosure.

FIG. 9B is a schematic cross-sectional view illustrating the electronic device in FIG. 9A along a section line V-V'.

FIG. 10 is a schematic partial top view illustrating an electronic device according to a tenth embodiment of the disclosure.

### DESCRIPTION OF THE EMBODIMENTS

In the disclosure, the electronic device can include a display device, a light-emitting device, a backlight device, a virtual reality (VR) device, an augmented reality (AR) device, an antenna device, a sensing device, a splicing device, or any combination thereof, which should however not be construed as a limitation in the disclosure. The display device can be a non-self-luminous display or a self-luminous display according to requirements and can be a color display or a monochrome display according to requirements. The antenna device can be a liquid crystal type antenna device or a non-liquid crystal type antenna device, the sensing device can be a device for sensing capacitance, light, thermal energy, or ultrasonic waves, and the splicing device can be a display splicing device or an antenna splicing device, which should however not be construed as a limitation in the disclosure. Electronic units in the electronic device can include passive elements and active elements, such as capacitors, resistors, inductors, diodes, transistors, and so on. The diode can include a light-emitting diode (LED) or a photodiode. The LED can include, for instance, an organic light emitting diode (OLED), a mini-LED, a micro-LED, or a quantum dot LED, which should however not be construed as a limitation in the disclosure. The transistor can include, for instance, a top gate thin film transistor, a bottom gate thin film transistor, or a dual gate thin film transistor, which should however not be construed as a limitation in the disclosure. The electronic device can further include fluorescence materials, phosphor materials, quantum dot (QD) materials, or other suitable materials according to requirements, which should however not be construed as a limitation in the disclosure. The electronic device can have a driving system, a control system, a light source system, and other peripheral systems to support the display device, the antenna device, the mounted device (including the AR device or the VR device, for instance), a vehicle-mounted device (including automobile windshields, for instance,), or the splicing device. It should be noted that the electronic device can be any arrangement or combination of the above, which should however not be construed as a limitation in the disclosure. The following descriptions are given by taking the electronic device as an example to explain the content of this disclosure, which should however not be construed as a limitation in the disclosure.

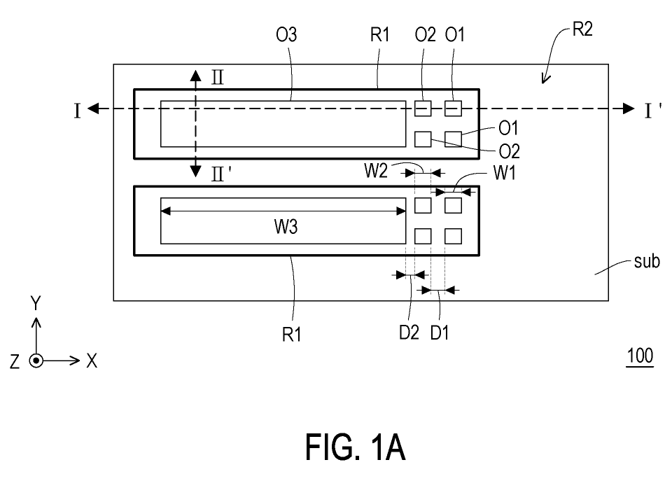

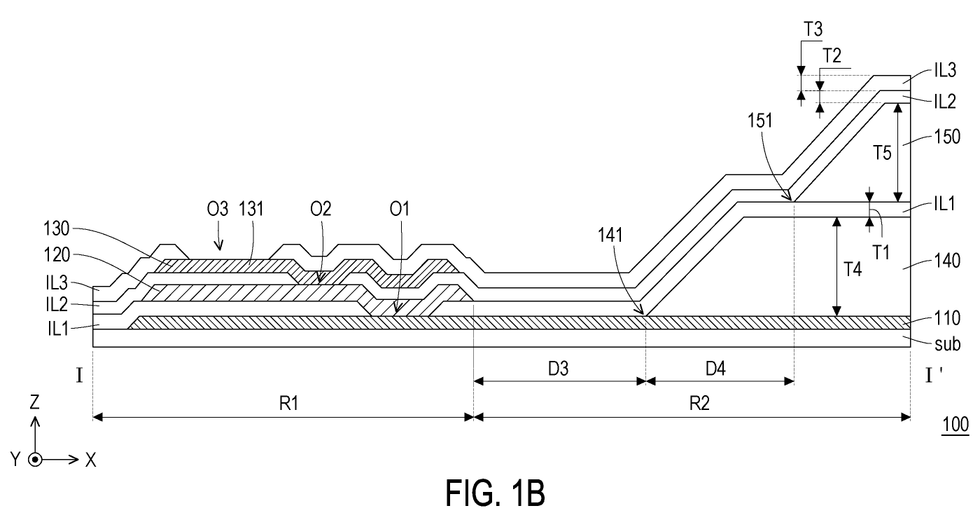

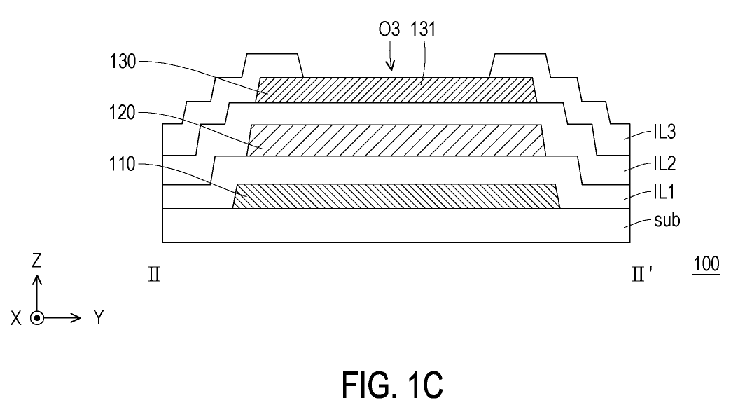

FIG. 1A is a schematic partial top view illustrating an electronic device according to a first embodiment of the disclosure. FIG. 1B is a schematic cross-sectional view illustrating the electronic device in FIG. 1A along a section line I-I'. FIG. 1C is a schematic cross-sectional view illustrating the electronic device in FIG. 1A along a section line II-II'. For clarity of the drawings and ease of explanation, several elements in the electronic device are omitted from illustration in FIG. 1A.

With reference to FIGS. 1A to 1C, an electronic device 100 provided in this embodiment includes a substrate sub, a first conductive layer 110, a first insulation layer IL1, a second conductive layer 120, a second insulation layer IL2, a third conductive layer 130, a third insulation layer IL3, a first planarization layer 140, and a second planarization layer 150.

Specifically, the substrate sub has a first region R1 and a second region R2 that are adjacent to each other. FIG. 1A schematically illustrates a plurality of the first regions R1, which should however not be construed as a limitation in the disclosure. In this embodiment, the first region R1 can be a pad region for bonding electronic elements (not shown in the drawings) to the electronic device 100, the second region R2 can be a region outside the pad region, and the second region R2 can include a sensing region, which should however not be construed as a limitation in the disclosure. The electronic elements can include a chip-on-film (COF), a flexible printed circuit board (FPC), or a chip for transmitting signals in or receiving signals out, which should however not be construed as a limitation in the disclosure. In this embodiment, the substrate sub can include a rigid substrate material, a flexible substrate material, or a combination thereof. For instance, the material of the substrate sub may include glass, quartz, sapphire, ceramics, polycarbonate (PC), polyimide (PI), polyethylene terephthalate (PET), other suitable substrate materials, or a combination thereof, which should however not be construed as a limitation in the disclosure.

The first conductive layer 110 is disposed on the first region R1 of the substrate sub, and the first conductive layer 110 can expose a portion of the substrate sub. In this embodiment, the first conductive layer 110 can extend from the first region R1 to the second region R2, so that electrical signals between the first region R1 and the second region R2 can be transmitted through the first conductive layer 110, which should however not be construed as a limitation in the disclosure.

The first insulation layer IL1 is disposed on the first conductive layer 110, and the first insulation layer IL1 can cover a portion of the substrate sub. The first insulation layer IL1 can be disposed on the first region R1 and the second region R2 of the substrate sub. The first insulation layer IL1 includes a first opening O1, and the first opening O1 can expose a portion of the first conductive layer 110. The first opening O1 is disposed on the first region R1 but not disposed on the second region R2.

The second conductive layer 120 is disposed on the first insulation layer IL1 and in the first opening O1, and the second conductive layer 120 can expose a portion of the first insulation layer IL1. The second conductive layer 120 is disposed on the first region R1. The second conductive layer 120 can be electronically connected to the first conductive layer 110 through the first opening O1.

The second insulation layer IL2 is disposed on the second conductive layer 120, and the second insulation layer IL2 can cover a portion of the first insulation layer IL1. The second insulation layer IL2 can be disposed on the first region R1 and the second region R2 of the substrate sub. The second insulation layer IL2 includes a second opening O2, and the second opening O2 can expose a portion of the second conductive layer 120. The second opening O2 is disposed on the first region R1 but not disposed on the second region R2. In this embodiment, in a direction Z, the second opening O2 does not overlap the first opening O1.

In this embodiment, a direction X, a direction Y, and the direction Z are different directions, respectively. The direction X is, for instance, an extension direction of a section line I-I', the direction Y is, for instance, an extension direction of a section line II-II', and the direction Z is, for instance, a normal direction of the substrate sub or a normal direction of the electronic device 100. Here, the direction X is substantially perpendicular to the direction Y, and both the direction X and the direction Y are substantially perpendicular to the direction Z, which should however not be construed as a limitation in the disclosure.

The third conductive layer 130 is disposed on the second insulation layer IL2 and in the second opening O2, and the third conductive layer 130 can expose a portion of the second insulation layer IL2. The third conductive layer 130 is disposed on the first region R1. The third conductive layer 130 can be electronically connected to the second conductive layer 120 through the second opening O2.

The third insulation layer IL3 is disposed on the third conductive layer 130, and the third insulation layer IL3 can cover a portion of the second insulation layer IL2. The third insulation layer IL3 can be disposed on the first region R1 and the second region R2 of the substrate sub. The third insulation layer IL3 includes a third opening O3, and the third opening O3 can expose a portion 131 of the third conductive layer 130. The third opening O3 is disposed on the first region R1 but not disposed on the second region R2. In this embodiment, the portion 131 of the third conductive layer 130 exposed by the third opening O3 can serve as a bonding region and an electronic connection region of the aforementioned electronic elements. Besides, in some embodiments, the aforementioned electronic elements can be bonded to the portion 131 of the third conductive layer 130 through an anisotropic conductive film (ACF) or other suitable conductive components, which should however not be construed as a limitation in the disclosure.

In this embodiment, in the direction Z, since the third opening O3 does not overlap the second opening O2 and the first opening O1, the flatness of the terrain of the first region R1 (or the pad region) used for bonding to the aforementioned electronic elements can be improved, thereby improving the bonding performance of the aforementioned electronic elements bonded to the first region R1 or improving the production amount of the electronic device 100. Moreover, in this embodiment, the third opening O3 can overlap the first conductive layer 110 and the second conductive layer 120.

In this embodiment, in the top view shown in FIG. 1A, a width W3 of the third opening O3 can be greater than a width W2 of the second opening O2 and a width W1 of the first opening O1 (i.e., W3>W2 and W3>W1), the width W3 of the third opening O3 can be greater than a distance D1 between the first opening O1 and the second opening O2 (i.e., W3>D1), and the width W3 of the third opening O3 can be greater than a distance D2 between the second opening O2 and the third opening O3 (i.e., W3>D2). This design can help improve the flatness of the terrain of the first region R1 (or the pad region), increase the contact area of the ACF bonded to the first region R1, or enhance the ability to resist electrostatic discharge (ESD), which should however not be construed as a limitation in the disclosure. Here, the width W1, the width W2, and the width W3 can be the minimum distances measured along the direction X of the first opening O1, the second opening O2, and the third opening O3, respectively. The distance D1 can be the minimum distance measured along the direction X between the first opening O1 and the second opening O2. The distance D2 can be the minimum distance measured along the direction X between the second opening O2 and the third opening O3. Besides, in this embodiment, the width W1, the width W2, the width W3, the distance D1, and the distance D2 are all greater than or equal to 2 micrometers (μm), which should however not be construed as a limitation in the disclosure.

In this embodiment, in the top view shown in FIG. 1A, the area of the third opening O3 can be greater than the area of the second opening O2 and the area of the first opening O1, which should however not be construed as a limitation in the disclosure.

In this embodiment, in the top view shown in FIG. 1A, all of the second openings O2 are positioned closer to the third opening O3 than all of the first openings O1 are, which should however not be construed as a limitation in the disclosure.

The first planarization layer 140 is disposed on the second region R2 of the substrate sub. In this embodiment, the first planarization layer 140 can be disposed on the first conductive layer 110 extending to the second region R2, which should however not be construed as a limitation in the disclosure. The first planarization layer 140 has an edge 141 adjacent to the first region R1.

The second planarization layer 150 is disposed on the second region R2 of the substrate sub, the first planarization layer 140, and the first insulation layer IL1. The second planarization layer 150 has an edge 151 adjacent to the first region R1.

In this embodiment, since a thickness T1 of the first insulation layer IL1, a thickness T2 of the second insulation layer IL2, and a thickness T3 of the third insulation layer IL3 are all smaller in the direction Z than a thickness T4 of the first planarization layer 140 and a thickness T5 of the second planarization layer 150, by not disposing the first planarization layer 140 and the second planarization layer 150 on the first region R1 (or by having the first planarization layer 140 and the second planarization layer 150 not overlapping the first region R1), the probability of the first planarization layer 140 and the second planarization layer 150 spatially interfering with the bonding of the electronic elements can be reduced. Here, the thickness T1, the thickness T2, the thickness T3, the thickness T4, and the thickness T5 can be thicknesses measured along the direction Z of the first insulation layer IL1, the second insulation layer IL2, the third insulation layer IL3, the first planarization layer 140, and the second planarization layer 150, respectively.

In this embodiment, a distance D3 between the first region R1 and the edge 141 of the first planarization layer 140 can be greater than or equal to 20 μm, and a distance D4 between the edge 141 of the first planarization layer 140 and the edge 151 of the second planarization layer 150 can be greater than or equal to 20 μm, so as to reduce the probability of the first planarization layer 140 and the second planarization layer 150 spatially interfering with the bonding of the electronic elements, which should however not be construed as a limitation in the disclosure. Here, the distance D3 can be the minimum distance measured along the direction X between an edge of the first region R1 adjacent to the second region R2 and the edge 141 of the first planarization layer 140, and the distance D4 can be the minimum distance measured along the direction X between the edge 141 of the first planarization layer 140 and the edge 151 of the second planarization layer 150.

Other embodiments are provided hereinafter for further explanation. Note that the reference numbers and a part of the contents in the previous embodiment are used in the following embodiments, in which identical reference numbers indicate identical or similar components, and the description of similar technical content should be referenced to the above-mentioned embodiments and thus will not be repeated in the following embodiments.

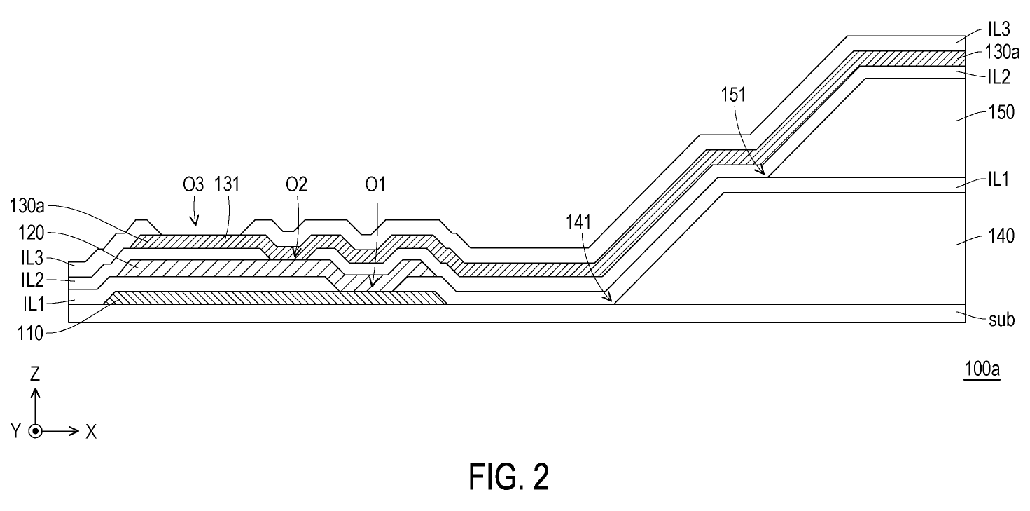

FIG. 2 is a partial cross-sectional schematic view illustrating an electronic device according to a second embodiment of the disclosure. With reference to both FIGS. 2 and 1B, an electronic device 100a provided in this embodiment resembles the electronic device 100 in FIG. 1B, while the difference therebetween lies in that: in the electronic device 100a provided in this embodiment, a third conductive layer 130a can extend from the first region R1 to the second region R2, so that electrical signals between the first region R1 and the second region R2 can be transmitted through the third conductive layer 130a.

Specifically, with reference to FIG. 2, the third conductive layer 130a extending to the second region R2 can be disposed on the second planarization layer 150, so that the second planarization layer 150 is located between the third conductive layer 130a extending to the second region R2 and the first planarization layer 140. Besides, in this embodiment, the first conductive layer 110 is disposed on the first region R1 of the substrate sub, and the first conductive layer 110 does not extend from the first region R1 to the second region R2.

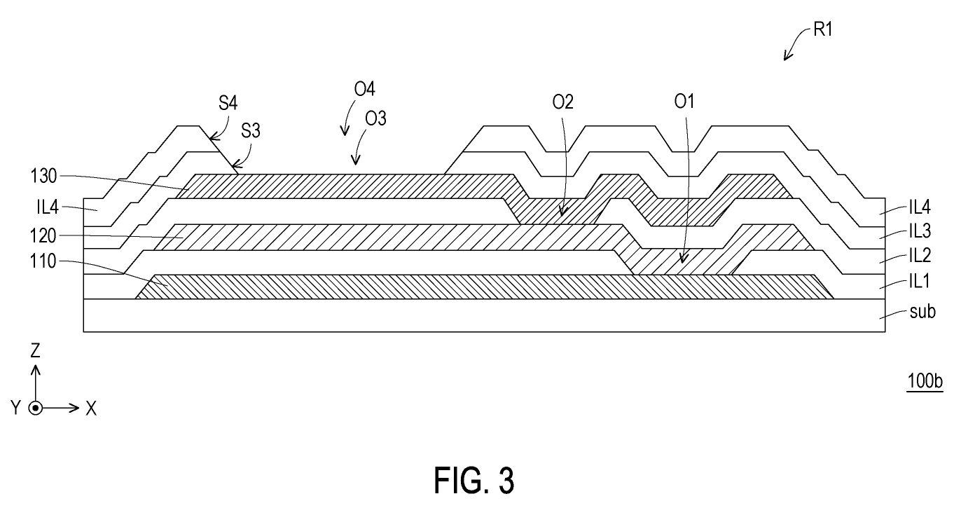

FIG. 3 is a partial cross-sectional schematic view illustrating an electronic device according to a third embodiment of the disclosure. For clarity of the drawing and convenience of explanation, FIG. 3 omits illustrating the first planarization layer and the second planarization layer in the electronic device. With reference to both FIGS. 3 and 1B, an electronic device 100b provided in this embodiment resembles the electronic device 100 in FIG. 1B, while the difference therebetween lies in that: the electronic device 100b provided in this embodiment further includes a fourth insulation layer IL4.

Specifically, with reference to FIG. 3, the fourth insulation layer IL4 is disposed on the third insulation layer IL3. The fourth insulation layer IL4 can be disposed on the first region R1 and the second region (not shown) of the substrate sub. The fourth insulation layer IL4 includes a fourth opening O4, the fourth opening O4 can expose a portion 131 of the third conductive layer 130, and the fourth opening O4 can be connected to the third opening O3. The fourth opening O4 is disposed on the first region R1 but is not disposed on the second region. In this embodiment, in the direction Z, the fourth opening O4 overlaps the third opening O3, and the fourth opening O4 does not overlap the second opening O2 and the first opening O1. Besides, in this embodiment, a sidewall S4 of the fourth opening O4 can be aligned with a sidewall S3 of the third opening O3, which should however not be construed as a limitation in the disclosure.

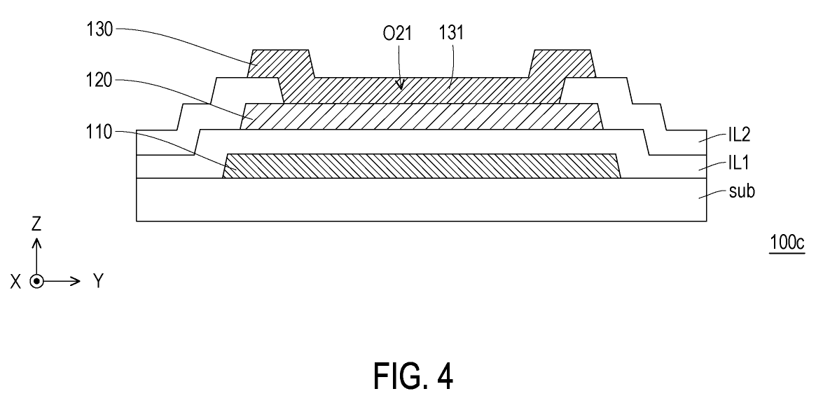

FIG. 4 is a partial cross-sectional schematic view illustrating an electronic device according to a fourth embodiment of the disclosure. With reference to both FIG. 4 and FIG. 1C, an electronic device 100c provided in this embodiment resembles the electronic device 100 in FIG. 1C, while the difference therebetween lies in that: in the electronic device 100c provided in this embodiment, the second insulation layer IL2 further includes another second opening O21.

Specifically, with reference to FIG. 4, the second opening O21 can expose a portion of the second conductive layer 120. The second opening O21 is disposed on the first region R1 and is not disposed on the second region (not shown in the drawings). In this embodiment, in the direction Z, the second opening O21 does not overlap the first opening (not shown in the drawings), and the second opening O21 can overlap the first conductive layer 110 and the second conductive layer 120. The third conductive layer 130 can be electronically connected to the second conductive layer 120 through the second opening O21.

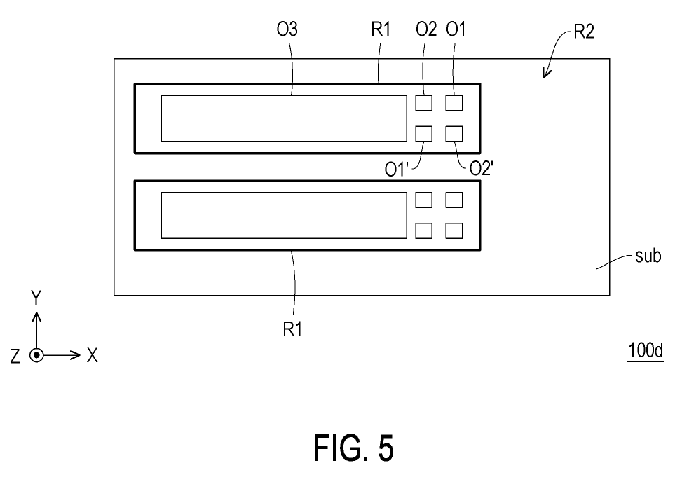

FIG. 5 is a schematic top view illustrating a partial electronic device according to a fifth embodiment of the disclosure. With reference to both FIGS. 5 and 1A, an electronic device 100d provided in this embodiment resembles the electronic device 100 in FIG. 1A, while the difference therebetween lies in that: in the top view illustrating the electronic device 100d provided in this embodiment, a portion of the second opening O2 is positioned closer to the third opening O3 than a portion of the first opening O1 is, and another portion of the first opening O1' is positioned closer to the third opening O3 than another portion of the second opening O2' is.

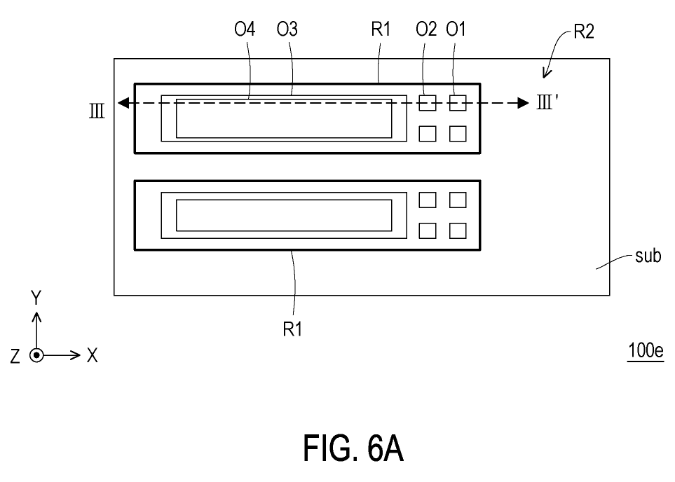

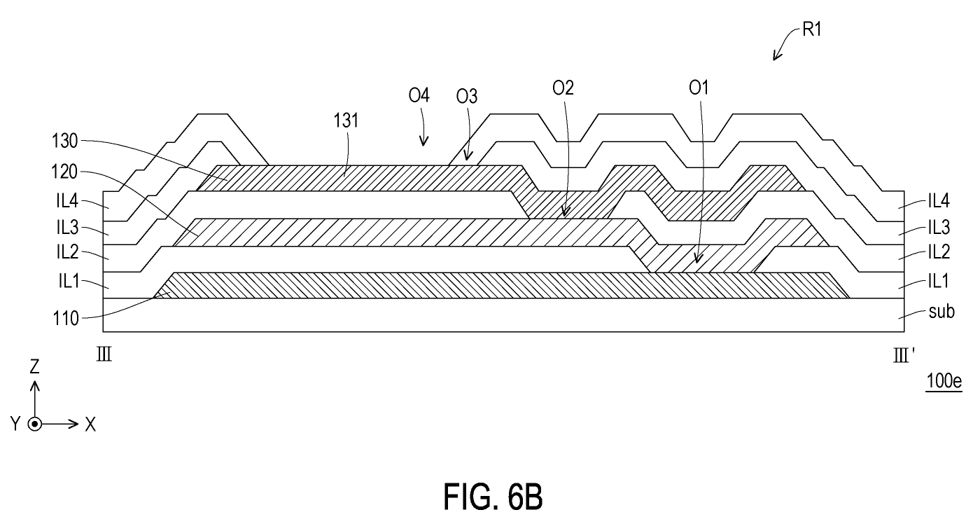

FIG. 6A is a schematic top view illustrating a partial electronic device according to a sixth embodiment of the disclosure. FIG. 6B is a cross-sectional schematic view illustrating the electronic device in FIG. 6A along a section line III-III'. For clarity of the drawings and ease of explanation, FIG. 6A omits illustrating several elements in the electronic device, and FIG. 6B omits illustrating the first planarization layer and the second planarization layer in the electronic device. With reference to both FIGS. 6A and 6B and 1A and 1B, an electronic device 100e provided in this embodiment resembles the electronic device 100 in FIGS. 1A and 1B, while the difference therebetween lies in that: the electronic device 100e provided in this embodiment further includes a fourth insulation layer IL4.

Specifically, with reference to FIGS. 6A and 6B, the fourth insulation layer IL4 is disposed on the third insulation layer IL3 and in the third opening O3. The fourth insulation layer IL4 can be disposed on the first region R1 and the second region R2 of the substrate sub. The fourth insulation layer IL4 includes a fourth opening O4, the fourth opening O4 can expose a portion 131 of the third conductive layer 130, and the fourth opening O4 is disposed in the third opening O3. The fourth opening O4 is disposed on first region R1 and is not disposed on the second region. In this embodiment, in the direction Z, the fourth opening O4 overlaps the third opening O3, and the fourth opening O4 does not overlap the second opening O2 and the first opening O1. Besides, in the top view as shown in FIG. 6A, the area of the fourth opening O4 can be smaller than the area of the third opening O3.

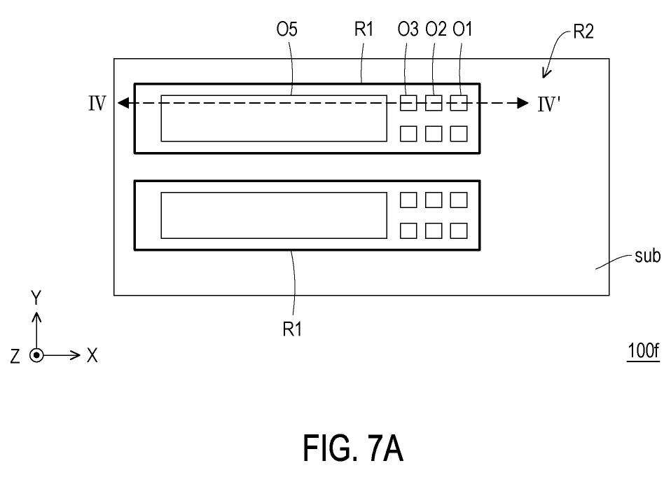

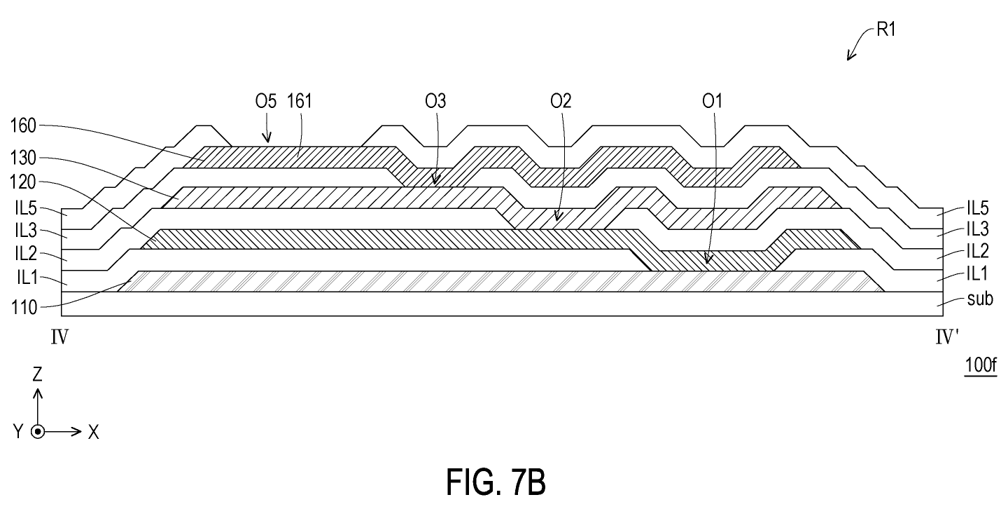

FIG. 7A is a schematic top view illustrating a partial electronic device according to a seventh embodiment of the disclosure. FIG. 7B is a cross-sectional schematic view illustrating the electronic device in FIG. 7A along a section line IV-IV'. For clarity of the drawings and ease of explanation, FIG. 7A omits illustrating several elements in the electronic device, and FIG. 7B omits illustrating the first planarization layer and the second planarization layer in the electronic device. With reference to both FIGS. 7A and 7B and 1A and 1B, an electronic device 100f provided in this embodiment resembles the electronic device 100 in FIGS. 1A and 1B, while the difference therebetween lies in that: the electronic device 100f provided in this embodiment further includes a fourth conductive layer 160 and a fifth insulation layer IL5.

Specifically, with reference to FIGS. 7A and 7B, the fourth conductive layer 160 is disposed on the third insulation layer IL3 and in the third opening O3, and the fourth conductive layer 160 can expose a portion of the third insulation layer IL3. The fourth conductive layer 160 is disposed on the first region R1. The fourth conductive layer 160 can be electronically connected to the third conductive layer 130 through the third opening O3.

The fifth insulation layer IL5 is disposed on the fourth conductive layer 160, and the fifth insulation layer IL5 can cover a portion of the third insulation layer IL3. The fifth insulation layer IL5 can be disposed on the first region R1 and the second region R2 of the substrate sub. The fifth insulation layer IL5 includes a fifth opening O5, and the fifth opening O5 can expose a portion 161 of the fourth conductive layer 160. The fifth opening O5 is disposed on the first region R1 and is not disposed on the second region R2. In this embodiment, in the direction Z, the fifth opening O5 does not overlap the third opening O3, the second opening O2, and the first opening O1. In this embodiment, the portion 161 of the fourth conductive layer 160 exposed by the fifth opening O5 can serve as a bonding region and an electronic connection region of the aforementioned electronic elements.

In this embodiment, in the top view as shown in FIG. 7A, the area of the fifth opening O5 can be greater than the area of the first opening O1, the area of the second opening O2, and the area of the third opening O3, which should however not be construed as a limitation in the disclosure.

In this embodiment, in the top view of the electronic device 100f, all of the third openings O3 are positioned closer to the fifth opening O5 than all of the second openings O2 and all of the first openings O1, which should however not be construed as a limitation in the disclosure.

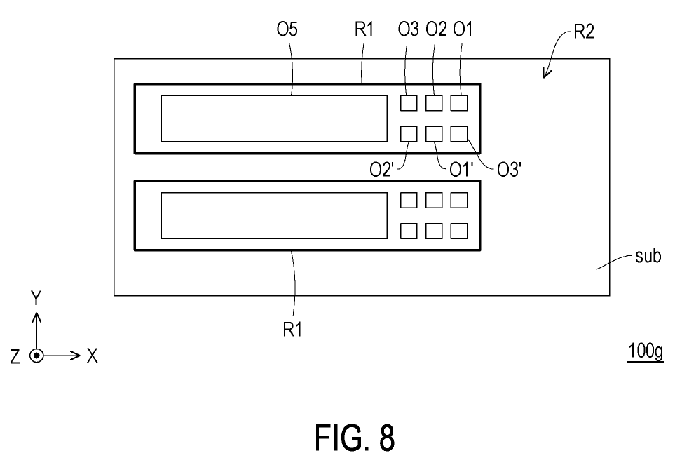

FIG. 8 is a schematic top view illustrating a partial electronic device according to an eighth embodiment of the disclosure. With reference to both FIGS. 8 and 7A, an electronic device 100g provided in this embodiment resembles the electronic device 100f in FIG. 7A, while the difference therebetween lies in that: in the top view of the electronic device 100g provided in this embodiment, a portion of the third openings O3 is positioned closer to the fifth opening O5 than a portion of the second openings O2 and a portion of the first openings O1, and another portion of the second openings O2' and another portion of the first openings O1' are positioned closer to the fifth opening O5 than another portion of the third openings O3'.

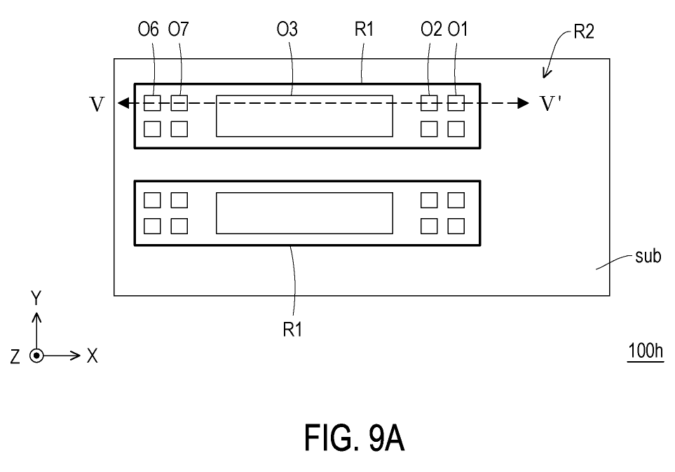

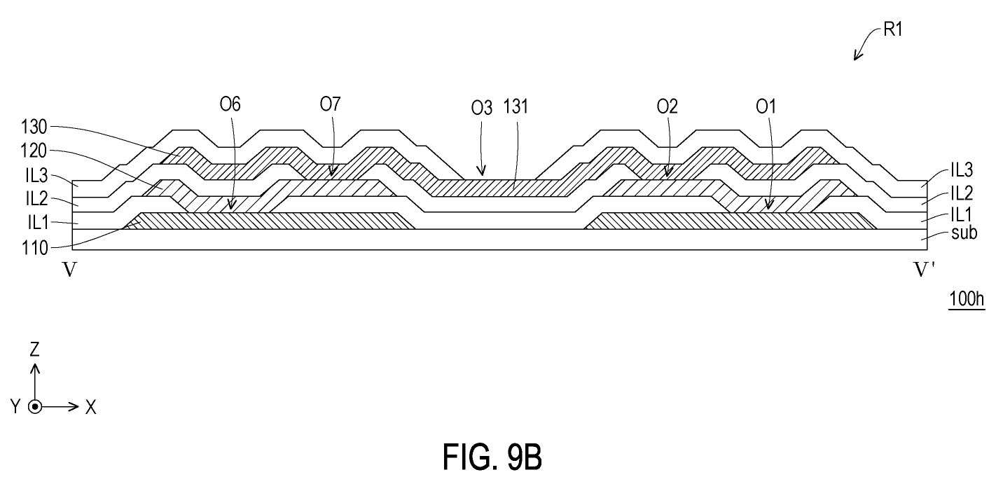

FIG. 9A is a schematic top view illustrating a partial electronic device according to a ninth embodiment of the disclosure. FIG. 9B is a schematic cross-sectional view illustrating the electronic device in FIG. 9A along a section line V-V'. For clarity of the drawings and ease of explanation, FIG. 9A omits the illustration of several elements in the electronic device, and FIG. 9B omits the illustration of the first planarization layer and the second planarization layer in the electronic device. With reference to both FIGS. 9A and 9B and 1A and 1B, an electronic device 100h provided in this embodiment resembles the electronic device 100 in FIGS. 1A and 1B, while the difference therebetween lies in that: in the electronic device 100h provided in this embodiment, the first insulation layer IL1 further includes a sixth opening O6, and the second insulation layer IL2 further includes a seventh opening O7.

Specifically, with reference to FIG. 9A, in the top view of the electronic device 100h, the third opening O3 is located between the first opening O1 and the sixth opening O6, and the third opening O3 is located between the second opening O2 and the seventh opening O7. Besides, in the top view as shown in FIG. 9A, all of the seventh openings O7 are positioned closer to the third opening O3 than all of the sixth openings O6, which should however not be construed as a limitation in the disclosure.

With reference to FIG. 9B, the sixth opening O6 can expose a portion of the first conductive layer 110, and the seventh opening O7 can expose a portion of the second conductive layer 120. The sixth opening O6 and the seventh opening O7 are disposed on the first region R1 and not disposed on the second region R2. In this embodiment, in the direction Z, the seventh opening O7 does not overlap the sixth opening O6, and the third opening O3 does not overlap the sixth opening O6 and the seventh opening O7.

In this embodiment, the second conductive layer 120 can be electronically connected to the first conductive layer 110 through the first opening O1 or the sixth opening O6, and the third conductive layer 130 can be electronically connected to the second conductive layer 120 through the second opening O2 or the seventh opening O7. Besides, in this embodiment, since the third opening O3 does not overlap the first conductive layer 110 and the second conductive layer 120, the indentation score can be increased, or the bonding performance of the aforementioned electronic elements bonded to the portion 131 of the third conductive layer 130 exposed by the third opening O3 can be improved, which should however not be construed as a limitation in the disclosure. In this embodiment, the indentation score may refer to visibility of conductive ball indentations after the aforementioned electronic elements bonded to the portion 131 of the third conductive layer 130 through the ACF including the conductive ball.

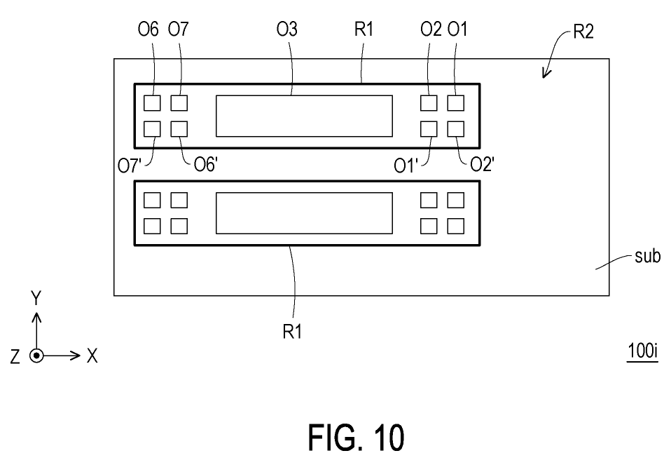

FIG. 10 is a schematic top view illustrating a partial electronic device according to a tenth embodiment of the disclosure. With reference to both FIGS. 10 and 9A, an electronic device 100i provided in this embodiment resembles the electronic device 100h in FIG. 9A, while the difference therebetween lies in that: in the top view of the electronic device 100i provided in this embodiment, a portion of the second openings O2 is positioned closer to the third opening O3 than a portion of the first openings O1 is, and another portion of the first openings O1' is positioned closer to the third opening O3 than another portion of the second openings O2' is; a portion of the seventh openings O7 is positioned closer to the third opening O3 than a portion of the sixth openings O6 is, and another portion of the sixth openings O6' is positioned closer to the third opening O3 than another portion of the seventh openings O7' is.

To sum up, in the electronic device provided in one or more embodiments of the disclosure, since the third opening does not overlap the second opening and the first opening, the flatness of the terrain of the first region (or the pad region) can be improved, thereby improving the bonding performance of the electronic elements bonded to the first region or increasing the production amount of the electronic device. Since the width of the third opening can be greater than the width of the second opening, the width of the first opening, the distance between the first opening and the second opening, or the distance between the second opening and the third opening, the flatness of the terrain of the first region (or the pad region) can be improved, the contact area of the ACF bonded to the first region can be increased, or the ability to resist the ED can be enhanced. Since the first planarization layer and the second planarization layer do not overlap the first region (or the distance between the first region and the edge of the first planarization layer can be greater than or equal to 20 μm), the probability of the first planarization layer and the second planarization layer spatially interfering with the bonding of the electronic elements can be reduced.

What is claimed is:

1. An electronic device, comprising:
a substrate;
a first conductive layer, disposed on the substrate;
a first insulation layer, disposed on the first conductive layer and comprising a first opening;
a second conductive layer, disposed on the first insulation layer, and electronically connected to the first conductive layer through the first opening;
a second insulation layer, disposed on the second conductive layer and comprising a second opening; and
a third conductive layer, disposed on the second insulation layer, and electronically connected to the second conductive layer through the second opening,
wherein the second opening does not overlap the first opening.

2. The electronic device according to claim 1, further comprising:
a third insulation layer, disposed on the third conductive layer and comprising a third opening,
wherein the third opening does not overlap the second opening.

3. The electronic device according to claim 2, further comprising:
a fourth insulation layer, disposed on the third insulation layer and comprising a fourth opening,
wherein the fourth opening overlaps the third opening.

4. The electronic device according to claim 3, wherein the fourth opening is connected to the third opening.

5. The electronic device according to claim 4, wherein a sidewall of the fourth opening is aligned with a sidewall of the third opening.

6. The electronic device according to claim 3, wherein the fourth opening is disposed in the third opening, and an area of the fourth opening is smaller than an area of the third opening.

7. The electronic device according to claim 2, further comprising:
a fourth conductive layer, disposed on the third insulation layer, and electronically connected to the third conductive layer through the third opening; and
a fifth insulation layer, disposed on the fourth conductive layer and comprising a fifth opening,
wherein the fifth opening does not overlap the third opening.

8. The electronic device according to claim 7, wherein the fifth opening does not overlap the second opening and the first opening.

9. The electronic device according to claim 7, wherein, in a top view, the third opening is positioned closer to the fifth opening than the second opening is.

10. The electronic device according to claim 2, wherein the first insulation layer further comprises a sixth opening, and the third opening is located between the first opening and the sixth opening in a top view.

11. The electronic device according to claim 10, wherein the third opening does not overlap the first conductive layer and the second conductive layer.

12. The electronic device according to claim 2, wherein a width of the third opening is greater than a distance between the second opening and the third opening.

13. The electronic device according to claim 2, wherein the third opening does not overlap the first opening.

14. The electronic device according to claim 2, wherein the third opening exposes the third conductive layer.

15. The electronic device according to claim 2, wherein, in a top view, the second opening is positioned closer to the third opening than the first opening is.

16. The electronic device according to claim 1, wherein the substrate has a first region and a second region adjacent to each other, and the electronic device further comprises:
a first planarization layer, disposed on the second region; and
a second planarization layer, disposed on the second region and the first planarization layer,
wherein the first conductive layer, the second conductive layer, and the third conductive layer are disposed on the first region.

17. The electronic device according to claim 16, wherein the first conductive layer extends from the first region to the second region, and the first planarization layer is disposed on the first conductive layer extending to the second region.

18. The electronic device according to claim 16, wherein the third conductive layer extends from the first region to the second region, and the third conductive layer extending to the second region is disposed on the second planarization layer.

19. The electronic device according to claim 16, wherein the first opening, the second opening, and the third opening are not disposed on the second region.

20. The electronic device according to claim 16, wherein the first planarization layer and the second planarization layer are not disposed on the first region.
